(19) United States
(12) Patent Application Publication
(10) Pub. No.: US 2026/0237452 A1
(43) Pub. Date: Aug. 13, 2026

(54) IN-MEMORY COMPUTATION DEVICE HAVING AN IMPROVED PROGRAMMING CIRCUIT AND PROGRAMMING METHOD

(71) Applicant: STMicroelectronics International N.V., Geneva (CH)

(72) Inventors: Marco PASOTTI, Travaco' Siccomario (PV) (IT); Riccardo ZURLA, Binasco (IT); Jacopo John BERTOLINI AGNOLETTO, Milano (IT); Emanuela CALVETTI, Villa d'Adda (IT)

(73) Assignee: STMicroelectronics International N.V., Geneva (CH)

(21) Appl. No.: 19/534,028

(22) Filed: Feb. 9, 2026

(30) Foreign Application Priority Data
Feb. 10, 2025 (IT) 102025000002463

(51) Int. Cl. G11C 29/52; G11C 13/00

(52) U.S. Cl. CPC G11C 29/52; G11C 13/0061; G11C 13/0069

(57) ABSTRACT

An in-memory computation device for performing an in-memory computation operation has a programming circuit. The programming circuit maps a signed computational weight into a group of memory cells of the IMC device. The group of cells has a first set of cells and a second set of cells that are configured to provide, during the execution of the in-memory computation operation, current contributions as a function of their respective programming and having opposite signs to each other. The programming circuit programs a memory cell based on the computational weight, detects a programming error of the memory cell of the first set of cells, and programs a memory cell of the second set of cells to account for the detected programming error.

### PRIORITY CLAIM

This application claims the priority benefit of Italian Application for U.S. Pat. No. 10,202,5000002463 filed on Feb. 10, 2025, the content of which is hereby incorporated by reference in its entirety to the maximum extent allowable by law.

### TECHNICAL FIELD

The present invention relates to an in-memory computation (IMC) device having an improved programming circuit. Furthermore, the invention also refers to a related method for programming the IMC device.

### BACKGROUND

As is known, an in-memory computation device (IMC device) uses the specific arrangement of memory cells of a memory array to perform analog data processing.

For example, an IMC device is used to perform multiply and accumulate (MAC) operations, which are used for example to implement machine learning algorithms, such as for example neural networks.

A multiply and accumulate operation provides an output vector Y=y₁, . . . , y_{M} as a result of multiplying an input vector X=x₁, . . . , x_{N} by a computational weight vector or matrix G, for example:

$$[ \begin{matrix}{y}_{1} \\ {y}_{2} \\ ⋮ \\ {y}_{M}\end{matrix} ] = [ \begin{matrix}{g}_{11} & {g}_{12} & ⋯ & {g}_{1 N} \\ {g}_{21} & {g}_{22} & ⋯ & {g}_{2 N} \\ ⋮ & ⋮ & ⋮ & ⋮ \\ {g}_{M 1} & {g}_{M 2} & ⋯ & {g}_{MN}\end{matrix} ] \times [ \begin{matrix}{x}_{1} \\ {x}_{2} \\ ⋮ \\ {x}_{N}\end{matrix} ] ,$$

that is:

$$\{ \begin{matrix}{y}_{1} = {g}_{11} \cdot {x}_{1} + {g}_{12} \cdot {x}_{2} + ⋯ + {g}_{1 N} \cdot {x}_{N} \\ {y}_{2} = {g}_{21} \cdot {x}_{1} + {g}_{22} \cdot {x}_{2} + ⋯ + {g}_{2 N} \cdot {x}_{N} \\ ⋮ \\ {y}_{M} = {g}_{M 1} \cdot {x}_{1} + {g}_{M 2} \cdot {x}_{2} + ⋯ + {g}_{MN} \cdot {x}_{N}\end{matrix} .$$

The IMC device stores the computational weights gᵢⱼ in the memory cells and performs the multiplication and addition operations at the cell level.

In detail, for each value yᵢ of the output vector Y, known IMC devices generate a current indicative of a respective MAC operation, that is

$${y}_{i} = {\sum }_{j = 1}^{j = N} {g}_{ij} \cdot {x}_{j} ,$$

and comprise a read circuit having a respective analog-to-digital converter (ADC) that discretizes said current.

IMC devices allow avoiding the back-and-forth transfer of data between a memory and a processing unit. As a result, the performance of an IMC device is not limited by the data transfer bandwidth between memory and processing unit and has low power consumption.

Applications are also known where a need is felt to perform signed MAC operations, for example wherein the computational weights gᵢⱼ may assume positive or negative values. As a result, the output values y₁, . . . , y_{M} may also assume positive or negative values, depending on the specific combination of input values and computational weights.

According to one approach, to map a computational weight gᵢⱼ that may assume positive and negative values into the memory array, two memory cells are used, each programmable at a SET state (i.e., a high-conductance state) or at a RESET state (i.e., a low-conductance state).

Of the two memory cells, a first memory cell is referred to as the positive cell and the second memory cell is referred to as the negative cell.

In case it is desired to map a positive computational weight, the positive cell is programmed at the SET state, while the negative cell is programmed at the RESET state in such a way as to have the lowest possible conductance, i.e., capable of providing a current contribution substantially equal to zero.

Vice versa, in case it is desired to map a negative computational weight, the negative cell is programmed at the SET state, while the positive cell is programmed at the RESET state in such a way as to have the lowest possible conductance, i.e., capable of providing a current contribution substantially equal to zero.

The computation of the in-memory computation operation is performed using two computation windows, wherein in the first computation window the cell that gives a positive contribution (for example, the positive cell in case of a positive input) is activated and in the second window the cell that gives a negative contribution (for example, the negative cell in case of a positive input) is activated.

During the first computation window, the read circuit measures the charge contribution provided by the cell that gives a positive contribution. During the second computation window, the read circuit measures the charge contribution provided by the cell that gives a negative contribution.

From a differential reading of the charge measured during the first computation window and the charge measured during the second computation window, the memory device reconstructs the final signed result of the in-memory computation operation.

For example, in the case of a positive computational weight, the respective negative cell will therefore provide a substantially zero charge contribution. In other words, the negative cell does not contribute to the final result of the in-memory computation operation.

However, it is noted that this approach is subject to a low precision of the final result of the in-memory computation operation.

In fact, an error in programming the positive cell or the negative cell may have a significant impact on the mapping accuracy of the respective computational weight.

Furthermore, it is noted that for multilevel memory cells, that is memory cells that may be programmed at a RESET state and at a plurality of SET states, for example N SET levels wherein a generic level n has a greater conductance than level n-1, the programming precision decreases as the number of levels increases.

Therefore, the known approaches have a low precision and are not scalable to memory cells having a high number of levels.

There is accordingly a need in the art to overcome the disadvantages of the prior art.

### SUMMARY

Embodiments here in concern an in-memory computation device and a programming method.

In an embodiment, an in-memory computation (IMC) device is configured to perform an in-memory computation operation, wherein the IMC device comprises a memory array including a group of memory cells configured to provide an overall current contribution during the execution of the in-memory computation operation. The group of memory cells comprises a first set of memory cells configured to provide, during the execution of the in-memory computation operation, a first current contribution that is a function of the programming of the first set of memory cells, and a second set of memory cells configured to provide, during the execution of the in-memory computation operation, a second current contribution that is a function of the programming of the second set of memory cells. The overall current contribution is a function of a difference between the first current contribution and the second current contribution.

The IMC device further comprises a programming circuit configured to map a signed computational weight into the group of memory cells and is further configured to: program at least one memory cell of the first set of memory cells at a first programming state based on the computational weight; detect a programming error of the at least one memory cell of the first set of memory cells, the programming error being indicative of an error between a target programming state of the at least one memory cell of the first set of memory cells and an actual programmed state of the at least one memory cell of the first set of memory cells; and program at least one memory cell of the second set of memory cells at a corrective programming state, based on the programming error.

In an embodiment, a method is presented for mapping a signed computational weight into a group of memory cells of a memory array of an in-memory computation (IMC) device configured to perform an in-memory computation operation. The group of memory cells is configured to provide an overall current contribution, during the execution of the in-memory computation operation, which is a function of the signed computational weight. The group of memory cells comprises a first set of memory cells configured to provide a first current contribution during the execution of the in-memory computation operation that is a function of the programming of the first set of memory cells, and a second set of memory cells configured to provide a second current contribution during the execution of the in-memory computation operation that is a function of the programming of the second set of memory cells. The overall current contribution is a function of a difference between the first current contribution and the second current contribution.

The method comprises: programming at least one memory cell of the first set of memory cells at a first programming state, based on the computational weight; detecting a programming error of the at least one memory cell of the first set of memory cells, the programming error being indicative of an error between a target programming state of the at least one memory cell of the first set of memory cells and an actual programmed state of the at least one memory cell of the first set of memory cells; and programming at least one memory cell of the second set of memory cells at a corrective programming state, based on the programming error.

### BRIEF DESCRIPTION OF THE DRAWINGS

For a better understanding of the present invention, embodiments thereof are now described, purely by way of non-limiting example, with reference to the attached drawings, wherein:

FIG. 1 shows a block diagram of an in-memory computation device, according to one embodiment;

FIG. 2 shows a detailed circuit diagram of a group of memory cells of the device of FIG. 1;

FIG. 3 shows a schematic representation of the programming states of the memory cells of FIG. 2;

FIG. 4 shows a flowchart of a method for mapping a computational weight into the device of FIG. 1;

FIG. 5 shows a time diagram indicative of the execution of an in-memory computation operation by the device of FIG. 1;

FIG. 6 shows a schematic representation of the programming of the method of FIG. 4;

FIG. 7 shows a block diagram of an in-memory computation device;

FIG. 8 shows a detailed circuit diagram of a group of memory cells of the device of FIG. 7;

FIG. 9 shows a flowchart of a method for mapping a positive computational weight into the device of FIG. 7;

FIG. 10 shows a flowchart of a method for mapping a negative computational weight into the device of FIG. 7;

FIG. 11 shows a flowchart of a method for mapping a zero computational weight into the device of FIG. 7;

FIG. 12 shows a detailed block diagram of a digital detector of the IMC device of FIG. 7;

FIG. 13 shows a time diagram indicative of the execution of an in-memory computation operation by the device of FIG. 7;

FIG. 14 shows a block diagram of a portion of an in-memory computation device;

FIG. 15 shows an exemplary schematic representation of programming states of the memory cells of FIG. 14; and

FIG. 16 shows a flowchart of a programming method of the group of memory cells of FIG. 14.

### DETAILED DESCRIPTION

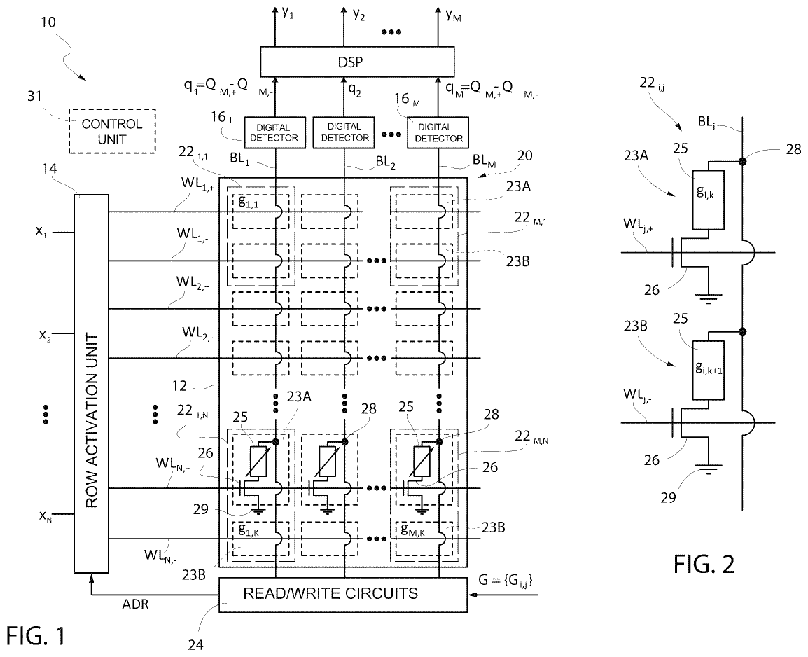

FIG. 1 shows an in-memory computation device (hereinafter, IMC device) 10 comprising a computation memory array (hereinafter for simplicity also referred to only as memory array or computation array) 12, a row activation unit or circuit 14, and an output processing circuit comprising herein a plurality of digital detectors 161, . . . , 16M and a digital processor (DSP) 17.

The memory array 12 comprises a plurality of memory cells 20 organized according to a matrix arrangement having M columns and K rows.

Hereinafter, a generic memory cell of the plurality of memory cells 20 is identified by 20_{i,k}, where the indices i=1, . . . , M and k=1, . . . , K indicate the column and, respectively, the row of the generic memory cell in the memory array 12.

In this embodiment, the memory cells 20 are of the non-volatile type.

The memory cells 20 are further organized so as to form a plurality of groups of memory cells 22 (identified by a dash-dot line in FIG. 1) configured to each store (map) a respective computational weight Gᵢⱼ.

Each computational weight Gᵢⱼ may have a sign and an absolute value. In practice, each computational weight Gᵢⱼ may be positive or negative (or zero).

The computational weights Gᵢⱼ may each represent a positive, negative, or zero number and may be used as weights to perform an in-memory computation operation (or calculation), in particular a signed Multiply and Accumulate (MAC) operation.

In this embodiment, each group of memory cells 22ᵢⱼ is formed by a respective set of positive cells, here a positive cell 23A, and a respective set of negative cells, here a negative cell 23B, belonging to the plurality of memory cells 20.

In the arrangement of FIG. 1, the positive memory cell 23A and the negative memory cell 23B of each group of cells 22 are arranged in a same column i and two adjacent rows k, k+1 of the memory array 12.

In practice, in this embodiment, the groups of memory cells 22 form a matrix having M columns and N rows, where N=K/2.

Hereinafter, a generic group of cells of the plurality of groups of cells 22 is indicated by 22ᵢⱼ, where the indices i=1, . . . , M and j=1, . . . , N indicate the column and, respectively, the row of the generic group of cells 22_{i,j.}

The memory cells 20 that are arranged in a same column i of the memory array 12 are mutually connected through a respective bit line BLᵢ, where i=1, . . . , M. The memory cells 20 arranged in the same row k of the memory array 12 are mutually connected through a respective word line WLₖ, where k=1, . . . , K.

In detail, each group of cells 22ᵢⱼ is coupled to two adjacent word lines WLₖ, WLₖ₊₁ which are hereinafter identified respectively as positive word line WL_{j,+} and negative word line WL_{j,-}.

With reference to the arrangement of FIG. 1, the positive word line WL_{j,+} is coupled to the positive cells 23A of the groups of cells 22_{1,j}, . . . , 22_{M,j} and the negative word line WL_{j,-} is coupled to the negative cells 23B of the groups of cells 22_{1,j}, . . . , 22_{M,j}.

For example, the positive word line WL_{1,+} is coupled to all the memory cells 20 that are arranged in row k=1 and columns i=1 to i=M of the memory array 12. The negative word line WL_{1,-} is coupled to all the memory cells 20 that are arranged in row k=2 and columns i=1 to i=M of the memory array 12.

In practice, each group of memory cells 22ᵢⱼ is coupled to a respective bit line BLᵢ and to two respective word lines WL_{j,+}, WL_{j,-}.

The row activation unit 14 is configured to provide each word line WLₖ, with k=1, . . . , K, with a respective electrical signal configured to activate the memory cells 20_{1,k}, . . . , 20_{M,k} that are coupled to the word line WLₖ.

As described in detail below, during the execution of an in-memory computation operation, each group of memory cells 22ᵢⱼ is configured to provide an overall current contribution that depends on the difference between the current contribution provided by the respective positive cell 23A and the current contribution provided by the respective negative cell 23B.

The IMC device 10 also comprises a read/write circuit 24, hereinafter also referred to as a programming circuit, configured to program (or write) the memory cells and to read the values written in the memory cells.

In detail, during a programming step of the memory array 12, the read/write circuit 24 receives a signal G indicative of the computational weights Gᵢⱼ to be programmed in the memory array 12.

Furthermore, during the programming step, the read/write circuit 24 may also provide an address signal ADR to the row activation unit 14 to control the activation of the memory cells that it is desired to program.

The IMC device 10 may comprise a control unit 31 configured to control the operation of one or more of: read/write circuit 24, row activation unit 14, digital detectors 16 and DSP 17, depending on the specific implementation and application.

FIG. 2 shows a detailed representation of a generic group of memory cells 22_{ij.}

In detail, the memory cells 20 each comprise a storage element 25 and a selection element 26.

The storage element 25 of each memory cell 20_{i,k} is a variable resistive element that may be programmed to have an electrical quantity, in particular a transconductance gik, that is modifiable, during the programming step of the memory array 12, as a function of the computational weight Gᵢⱼ of the respective group of cells 22ᵢⱼ, as discussed in detail below.

In particular, the storage element 25 may be based on a Phase Change Material (PCM), such as for example a chalcogenide.

A phase change material has at least two phase states, such as an amorphous phase and a crystalline phase, wherein each phase may have one or more distinct resistivity values.

A phase change material may be transformed from one phase state to another by heat transfer, for example using current pulses.

The resistance of each storage element 25 associated with the respective phase state is used to distinguish two or more logic states of the corresponding memory cell 20.

For example, the amorphous phase may have a higher resistance (and therefore a lower transconductance) than the crystalline phase.

For example, a logic state ‘0’, or reset state, may be associated with the amorphous phase of the storage element 25. A logic state ‘1’, or set state, may be associated with the crystalline phase of the storage element 25.

However, the memory cells 20 may be multilevel cells, that is they may be programmed so as to represent a number of logic states greater than two.

The storage element 25 has a first terminal coupled to a node 28 of the respective bit line BLᵢ and a second terminal coupled to a reference potential node, here to ground 29, through the selection element 26.

The selection element 26 is a switch, for example a BJT transistor, a diode or a MOS transistor, here an NMOS transistor, which is arranged in series with the respective storage element 25 and whose switching is controlled by a respective activation signal received on the respective word line WL_{j,+} or WL_{j,-}.

In this embodiment, the NMOS transistor forming the selection element 26 has the source terminal coupled, here directly connected, to ground 29; a drain terminal coupled, here directly connected, to the second terminal of the storage element 25; and a gate terminal coupled, here directly connected, to the respective word line WL_{j,+} or WL_{j,-} In practice, the storage element 25 and the selection element 26 form a current path of the respective memory cell 20.

In the following description reference will be made to one embodiment wherein the memory cells 20 are multilevel cells, that is each memory cell 20_{i,k} may be programmed so as to represent three or more logic states.

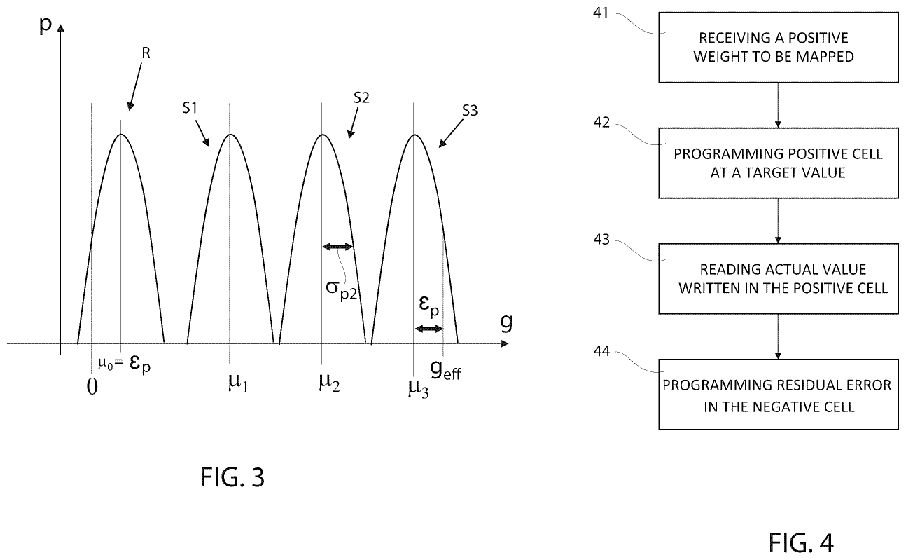

Purely by way of example, as shown in FIG. 3, hereinafter it is considered that each memory cell 20_{i,k} may be programmed at four levels L0, L1, L2, L3 including: one reset state R and three set states S1, S2, S3, wherein the transconductance g of each level follows the relationship: g(R)<g(S1)<g(S2)<g(S3).

In detail, each level L₁, with 1=0, . . . , 3 of the memory cells 20 may have a respective distribution of transconductance values, that depends on multiple factors including the technology of the memory cells 20, the specific typology of the resistive elements 25, the specific writing techniques used, etc.

In the example of FIG. 4, each level L₁ has a Gaussian distribution and comprises a theoretical mean value μ₁ of transconductance and a variance 61. The levels may have distributions that are equal to or different from each other, depending on the specific application, technology, etc.

With reference to FIG. 4, a method is now described for mapping a generic computational weight Gᵢⱼ into the respective group of memory cells 22_{i,j}.

The read/write circuit 24 receives, step 41, a signal indicative of the computational weight to be mapped Gᵢⱼ. Purely by way of example and for clarity of exposition, it is considered hereinafter that the computational weight to be mapped Gᵢⱼ is positive, that is representative of a number greater than zero.

Since the weight to be mapped Gᵢⱼ is positive, the read/write circuit 24 programs, step 42, the respective positive cell 23A of the group of cells 22ᵢⱼ at a set state that depends on the weight to be mapped Gᵢⱼ.

The read/write circuit 24 programs the positive cell 23A as a function of a target value corresponding to the set state at which it is intended to program the positive cell 23A, that is in such a way that the positive cell 23A is, in response to the programming of step 42, within the distribution of the desired set state.

In the embodiment considered, the positive cell 23A is programmed at one of the set levels S1, S2 or S3, as a function of the absolute value of the weight to be mapped Gᵢⱼ.

In detail, the read/write circuit 24 may provide the row activation unit 14 with the address signal ADR indicating the word line WLₖ to be activated. In response, the row activation unit 14 provides an activation signal to the word line WLₖ that is configured to close the selection element 26 of the positive cell 23A of the group 22ᵢⱼ, that is to close the current path between node 28 and ground 29 in the configuration of FIG. 2.

Successively, the read/write circuit 24 may provide an electrical programming signal, in particular a current (for example, a current pulse) to the bit line BLᵢ associated with the cell 23 A of the group 22ᵢⱼ, configured to set the cell 23A to the desired set state.

A respective electrical programming signal, previously defined during an initialization or calibration of the IMC device 10, may be associated with each level.

The level at which to program the positive cell 23A of the group of memory cells 22ᵢⱼ may depend on the absolute value of the weight to be mapped Gᵢⱼ. Furthermore, the level at which to program the positive cell 23A may also depend on the specific method used to perform an in-memory computation operation or on other parameters of the IMC device 10, depending on the specific application.

For example, levels having higher conductance may be used to map weights Gᵢⱼ having a higher absolute value.

With reference to the example of FIG. 3, the positive cell 23A of the group of cells 22ᵢⱼ is programmed at the third set level S3.

In the example considered, the electrical programming signal provided to the positive cell 23A is configured to have, as a programming target value, the mean value u3 associated with the set state S3.

In practice, the set state S3 and in particular the respective mean value u3 correspond to a target programming state at which the positive cell 23A is intended to be brought in response to the programming of step 42.

Then, step 43, the read/write circuit 24 reads the positive cell 23A of the group of memory cells 22ᵢⱼ, in such a way as to measure the transconductance value g_{eff} that has actually been programmed at the resistive element 25 at the end of step 42.

In fact, given the statistical distribution of the states at which the positive cell 23A may be programmed, as shown for example in FIG. 3, the value actually programmed in the positive cell 23A in response to the programming of step 42 may be different from the target value μ₃.

The reading of the positive cell 23A may comprise the activation of the positive cell 23A, similarly to what has been discussed for the write step 42, and the execution of a measurement of the conductance of the storage element 25.

Successively, step 44, the negative cell 23B of the group of memory cells 22ᵢⱼ is programmed as a function of the actual transconductance value g_{eff} written at step 42 in the positive cell 23A and read at step 43.

In detail, the negative cell 23B may be programmed as a function of the residual error εₚ that is indicative of the difference between the actual value g_{eff} and the target value, that is μ₃ in the example considered.

In detail, the read/write circuit 24 programs the negative cell 23B at a reset state R comprising a residual transconductance value gᵣ that is a function of the residual error Ep, in particular such that gᵣ=εₚ.

In practice, the reset state R may be configured in such a way that the respective mean value po of conductance is greater than zero and in particular equal to the residual error εₚ.

In other words, during step 44, the negative cell 23B is programmed at a reset state that is not centered around the minimum conductance value (for example equal to zero or substantially zero) that may be programmed in the negative cell 23B, but is programmed at a reset state that is shifted with respect to the minimum conductance value.

In practice, the reset state comprising the conductance value gᵣ is the corrective programming state at which it is desired to bring the negative cell 23B with step 44.

In particular, the read/write circuit 24 may activate the negative cell 23B of the group of cells 22ᵢⱼ through the respective word line WL_{j,-}, and provide a programming signal configured to set the transconductance of the respective storage element 25 to the residual value gᵣ. In particular, the negative cell 23B may be programmed at step 44 using an analog writing process.

In practice, in the example considered wherein it is desired to map a positive weight Gᵢⱼ, the negative cell 23B is not programmed at the reset state R with the lowest possible conductance (ideally, equal to zero) and regardless of the value actually programmed in the respective positive cell 23A; conversely, the negative cell 23B is programmed as a function of the programming error of the positive cell 23A.

This allows to correct any programming errors of the positive cell 23A, thus improving the mapping accuracy of the weight Gᵢⱼ.

It will be clear to the person skilled in the art that although the method of FIG. 4 has been described with reference to the mapping of a positive computational weight, what has been described may also be applied mutatis mutandis to the case in which it is desired to map a negative computational weight.

In particular, if it is desired to program a negative computational weight, at step 42 the respective negative cell 23B will be programmed at the target value of one of the set states; at step 43 the value actually written in the negative cell 23B is read; and at step 44 the residual programming error of the negative cell is programmed in the respective positive cell 23A.

It will also be clear that what has been described above may be applied to map a respective computational weight Gᵢⱼ into each of the groups of memory cells 22_{ij.}

Following the programming of the memory array 12, the IMC device 10 may be used to perform an in-memory computation operation, for example a multiply and accumulate, MAC, operation.

In detail, the row activation unit 14 may receive an input vector X indicative of a plurality of input values x₁, . . . , x_{N}. The input values x₁, . . . , x_{N} each represent an input coefficient.

The input values x₁, . . . , x_{N} may be the input data of a MAC operation.

The row activation unit 14 is configured to provide, for each input value xⱼ, where j=1, . . . , N, a positive activation signal S_{j,+} to the respective positive word line WL_{j,+} and a negative activation signal S_{j,-} to the respective negative word line WL_{j,-}.

In practice, the row activation unit 14 provides the positive activation signal S_{j,+} to the positive cells 23A of the groups of cells 221j, . . . , 22_{M,j} and the negative activation signal S_{j,-} to the negative cells 23B of the groups of cells 22_{1,j}, . . . , 22_{M,j}.

The activation signals S_{j,+} and S_{j,-} are a function of the respective input value xⱼ; in particular, a function of the respective sign and/or absolute value.

In detail, each of the activation signals S_{j,+} and S_{j,-} is configured to activate the memory cells of the respective word line WL_{j,+} and WL_{j,-} for an activation duration T_{j,+}, T_{j,-} that is a function of the sign and/or absolute value of the respective input value xⱼ.

For example, the activation signals S_{j,+} and S_{j,-} may be pulses having a duration that depends on, in particular it may be equal to, the respective activation duration T_{j,+}, T_{j,-}.

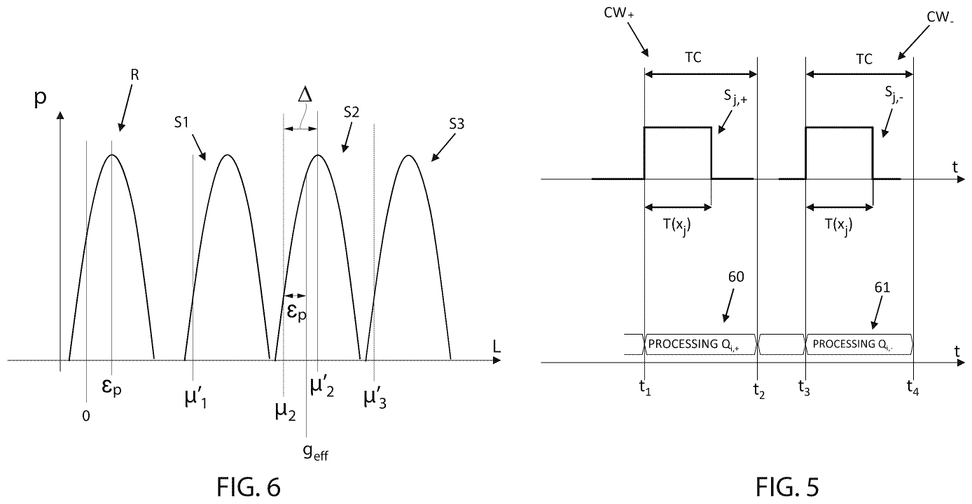

In the example of FIG. 5, for simplicity, the activation signals S_{j,+} and S_{j,-} have a same duration T(xⱼ); however, they may have different durations from each other depending on the specific implementation.

In detail, the row activation unit 14 provides the positive activation signals S_{j,+} with j=1, . . . , N during a computation window CW₊ (positive computation window), and the negative activation signals S_{j,-} with j=1, . . . , N during a computation window CW₋ (negative computation window), distinct from the positive computation window CW₊.

In the example of FIG. 5, the computation windows CW₊, CW₋ have a same duration TC; however, they may have different duration from each other depending on the specific implementation.

In practice, during the positive computation window CW₊, only the positive cells 23A of the groups of cells 22ᵢⱼ are activated, while the negative cells 23B of the groups of cells 22ᵢⱼ are not activated. Conversely, during the negative computation window CW₋, only the negative cells 23B of the groups of cells 22ᵢⱼ are activated, while the positive cells 23A of the groups of cells 22ᵢⱼ are not activated.

By considering a generic bit line BLᵢ as an example, during the positive computation window CW₊, the positive cells 23A of the groups of memory cells 22_{i,1}, . . . , 22_{1,N} each absorb, from the bit line BLᵢ, a respective cell current whose absolute value depends on the respective transconductance gᵢⱼ and whose duration depends on the time duration T(xⱼ) of the respective positive activation signal S_{j,+}.

During the positive computation window CW₊, the bit line BLᵢ is then flown through by a bit line current I_{BL,i,+} that is a function of the sum of the current contributions of all the positive cells 23A coupled to the bit line BLᵢ.

Similarly to what has been discussed above, during the negative computation window CW₋, the bit line BLⱼ is flown through by a bit line current I_{BL,i,-}that is a function of the sum of the current contributions of all the negative cells 23B coupled to the bit line BLᵢ.

The digital detector 16 coupled to the bit line BLᵢ is configured to measure the charge Q_{i,+} flowed in the bit line BLᵢ during the positive computation window CW₊ and the charge Q_{i,-} flowed in the bit line BLᵢ during the negative computation window CW₋.

In detail, the digital detector 16 is configured to integrate the bit line current I_{BL,i,+} flowed in the bit line BLᵢ during the positive computation window CW₊ and the bit line current I_{BL,i,+} flowed in the bit line BLᵢ during the negative computation window CW₋.

In particular, according to one embodiment and as shown in FIG. 5, the measurement of the charge Q_{i,+} may be performed during the positive computation window CW₊, and the measurement of the charge Q_{i,-} may be performed during the negative computation window CW₋.

The DSP 17 is configured to receive, for each bit line BLᵢ, signals indicative of the charges Q_{i,+} and Q_{i,-} measured by the digital detector 16, and to provide at output a respective output signal yᵢ as a function of the difference between the charge signals Q_{i,+} and Q_{i,-}; this difference is in fact indicative of the MAC operation

$${\sum }_{j = 1}^{N} {G}_{i , j} \cdot {x}_{j} .$$

It will be clear to the person skilled in the art that the fact that: for positive computational weights, the programming error read in the positive cells 23A is written in the respective negative cells 23B; and for negative computational weights, the programming error read in the negative cells 23B is written in the respective positive cells 23A, allows, during the execution of a MAC operation, the programming errors to be compensated and therefore the MAC operation may have a high precision.

Furthermore, the possibility of compensating for programming errors allows the present method to be scalable even in the cases of memory cells having a high number of levels.

Furthermore, considering for example the programming of a positive computational weight, the fact that the respective negative cell is not programmed at a conductance value equal to zero, but at a conductance value greater than zero as a function of the programming error of the respective positive cell, means that even the conductance value written in the negative cell may be subject, over time, to a drift. Since negative cells and positive cells may be implemented using the same technology, the drift undergone by a negative cell may correspond to the drift undergone by the respective positive cell; this entails that, during the execution of an in-memory computation operation wherein the charge contribution provided by the negative cells is subtracted from the charge contribution provided by the positive cells, the drift undergone by the positive and negative cells may self-compensate and therefore not negatively impact the calculation accuracy.

The IMC device 10 may therefore have high calculation accuracy during the execution of an in-memory computation operation.

FIG. 6 shows an illustrative schematic representation of the programming method described with reference to FIG. 4.

In detail, with reference to what has been described in reference to step 42 of FIG. 4, in the embodiment represented in FIG. 6, the positive cell (in the case of mapping a positive computational weight Gᵢⱼ) is programmed at a target value u′2 that is greater than the theoretical mean value μ₂ that would be associated with the respective set state S2.

In particular, the difference between the target value u′2 and the theoretical value μ₂ is indicated by Δ and may be, for example, lower than or equal to, in particular equal to, the maximum programming error; the maximum programming error, with reference to the representation of FIG. 6, may correspond to half the maximum width of the distribution associated with one or more of the states S1-S3.

In practice, in this embodiment, the programming of the positive cell 23A may be done by providing the positive cell 23A with a programming signal, for example a current pulse, configured to set the transconductance of the positive cell 23A to the target value u′2.

With reference to step 44 described in reference to FIG. 4, the residual error &p programmed in the negative cell 23B is a function of the difference between the actual value g_{eff} measured and the theoretical value μ₂.

The fact of setting as a target value in the programming of step 42 a value greater than the theoretical value associated with the SET state at which the positive cell 23A is intended to be programmed, allows to increase the capacity of compensating the programming error of the present method.

In fact, this allows to increase the probability that the value g_{eff} actually written in the positive cell 23A is greater than the theoretical value μ₂ associated with the set state S2. Therefore, the present method allows to increase the number of cases in which the value actually written in the positive cell 23A may be corrected by programming the respective negative cell 23B.

Therefore, during the execution of a MAC operation as discussed in reference to FIG. 5, it is possible to obtain a greater probability of compensation for programming errors and therefore further increase the precision of the MAC operations.

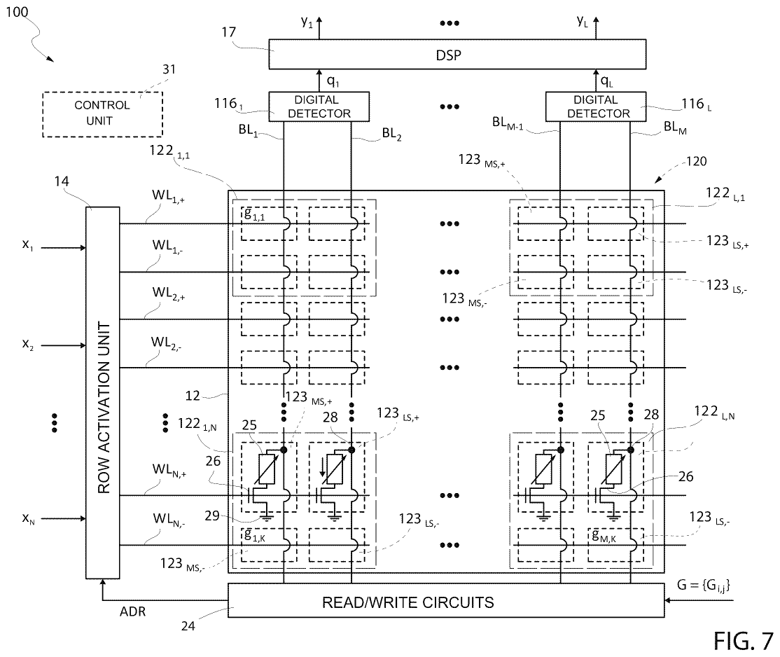

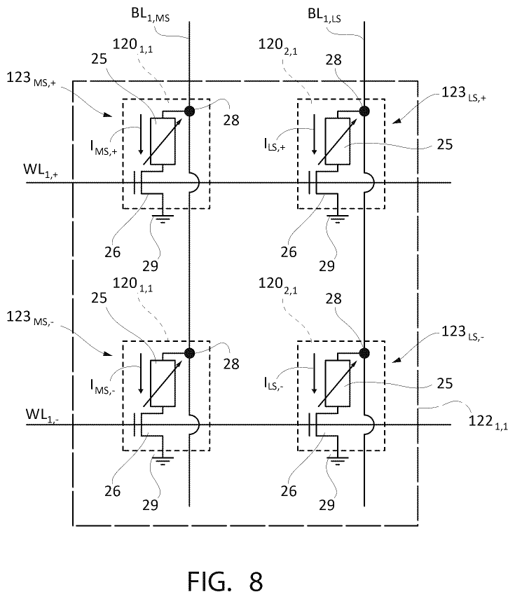

FIG. 7 shows an embodiment of the IMC device, indicated by the number 100.

The IMC device 100 has a general structure similar to that of the IMC device 10 of FIG. 1; therefore, elements in common are indicated by the same reference numbers used in the description of the IMC device 10 and are not further described in detail.

In particular, the memory array 12 also comprises in this embodiment a plurality of memory cells, indicated by 120, organized according to a matrix arrangement having M columns and K rows.

What has been discussed for the memory cells 20 of FIG. 1 also applies to the memory cells 120, unless otherwise specified.

Unlike the IMC device 10 of FIG. 1, in the IMC device 100 of FIG. 7 the memory cells 120 are organized so as to form a plurality of groups of memory cells, wherein each group of memory cells is indicated hereinafter by 122ᵢⱼ and identified by a dash-dot line in FIG. 7. Hereinafter, the plurality of groups of memory cells 122ᵢⱼ may also be indicated as a whole by the reference number 122.

Each group of memory cells 122ᵢⱼ is configured to store (map) a respective computational weight Gᵢⱼ that may be used to perform an in-memory computation operation, in particular a MAC operation.

The computational weight Gᵢⱼ may represent a positive, negative or zero number.

In detail, in the embodiment of FIG. 7 and as shown in the enlarged portion of FIG. 8, each group of memory cells 122ᵢⱼ comprises two positive cells, of which a most significant positive cell 123_{MS,+} and a least significant positive cell 123_{LS,+}, and two negative cells, of which a most significant negative cell 123_{MS,-} and a least significant negative cell 123_{LS,-}.

Hereinafter, for brevity, the most significant positive cell 123_{MS,+} may also be referred to only as cell 123_{MS,+}; the least significant positive cell 123_{LS,+} may also be referred to only as cell 123_{LS,+}; the most significant negative cell 123_{MS,-} may also be referred to only as cell 123_{MS,-}; and the least significant negative cell 123_{LS,-} may also be referred to only as cell 123_{LS,-}.

In the arrangement of FIGS. 7 and 8, the most significant cells 123_{MS,+} and 123_{MS,-} of each group of cells 122ᵢⱼ are coupled to a same bit line BLₘ and to two word lines WL_{j,+}, WL_{j,-} different from each other.

The least significant cells 123_{LS,+} and 123_{LS,-} of each group of cells 122ᵢⱼ are coupled to a same bit line BLₘ₊₁ and to two word lines WL_{j,+}, WL_{j,-} different from each other.

In practice, the most significant positive cell 123_{MS,+} is coupled to the same bit line BLₘ of the respective most significant negative cell 123_{MS,-}, and coupled to the same word line WL_{j,+} of the respective least significant positive cell 123_{LS,-}.

In practice, in this embodiment, the plurality of groups of memory cells 122 forms a matrix having L columns and N rows, where L=M/2 and N=K/2.

In detail, the plurality of groups of memory cells 122 comprises the groups of memory cells 122ᵢⱼ, where the indices i=1, . . . , L and j=1, . . . , N indicate the column and, respectively, the row of the generic group of cells 22_{i,j.}

Each group of memory cells 122ᵢⱼ is therefore associated with: a most significant bit line BL_{i,MS}, i.e., the bit line to which the respective most significant cells 123_{MS,+} and 123_{MS,-} are coupled; a least significant bit line BL_{i,LS}, i.e., the bit line to which the respective least significant cells 123_{LS,+} and 123_{LS,-} are coupled; a positive word line WL_{j,+}, i.e. the word line to which the respective positive cells 123_{MS,+} and 123_{LS,+} are coupled; and a negative word line WL_{j,-}, i.e. the word line to which the respective negative cells 123_{MS,-} and 123_{LS,-} are coupled.

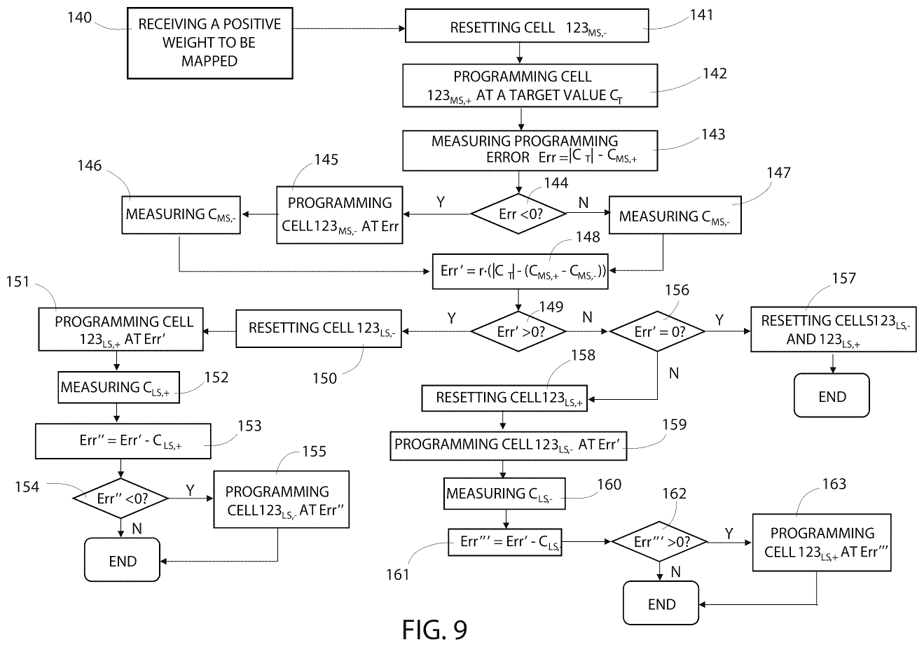

With reference to FIGS. 9-11, a method for mapping a computational weight Gᵢⱼ into a respective group of cells 122ᵢⱼ is described.

In detail, FIG. 9 shows a flowchart wherein the weight Gᵢⱼ to be mapped is positive.

The read/write circuit 24 receives, in step 140, the positive weight to be mapped Gᵢⱼ.

In particular, the weight Gᵢⱼ may be represented by a binary encoding of the weight to be mapped, or by a different encoding, depending on the specific implementation.

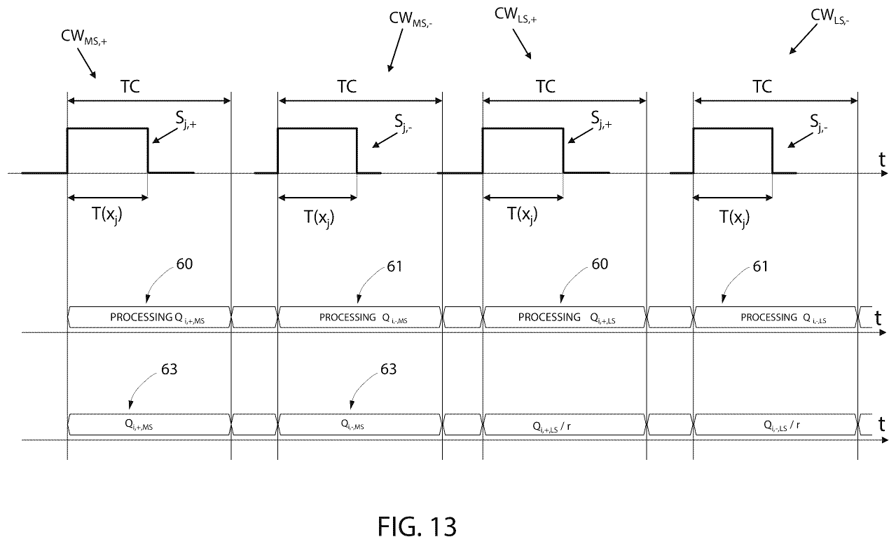

Furthermore, a target current value C_{T}, that is the overall current contribution that the group of cells 122ᵢⱼ is desired to provide during the execution of an in-memory computation operation, is associated with the weight to be mapped Gᵢⱼ. In detail, as described in more depth hereinafter in reference to FIGS. 12 and 13, the overall current contribution is a function of the difference between the current contribution provided by the set of positive cells (i.e., the sum of the current contribution of the cells 123_{MS,+} and 123_{LS,+} weighted as a function of the ratio between the significance of the cells 123_{MS,+} and 123_{LS,+}) and the current contribution provided by the set of negative cells (i.e., the sum of the current contribution of the cells 123_{MS,-} and 123_{LS,-} weighted as a function of the ratio between the significance of the cells 123_{MS,-} and 123_{LS,-}).

The target current value C_{T} may depend on multiple factors associated with the specific implementation of the IMC device 100.

Then, in step 141, the read/write circuit 24 resets the most significant negative cell 123_{MS,-}.

In practice, the read/write circuit 24 sets the cell 123_{MS,-} at the respective lowest conductance reset state.

At step 142, the read/write circuit 24 programs the cell 123_{MS,+} at the target current value C_{T}, in particular at the respective absolute value, that in this embodiment represents the target programming state for the cell 123_{MS,+}.

In detail, the read/write circuit 24 performs an analog programming of the cell 123_{MS,+}. For example, the analog programming may comprise a sequence of successive writing steps, in such a way as to gradually arrive at the target value C_{T}.

In detail, the analog programming according to the present invention may be understood as a multilevel programming, that is a programming that allows a memory cell to be programmed at a number of states greater than two.

According to one embodiment, the read/write circuit 24 may be configured to program the cell 123_{MS,+} at a current value higher than the target value C_{T}, for example at a value C_{T}+Δ, where the offset A may be defined as indicated above in reference to FIG. 6. This may allow the programming precision of the weight Gᵢⱼ to be increased.

Then, step 143, the programming error Err resulting from step 142 is measured.

In detail, the read/write circuit 24 carries out a reading indicative of the written resistance (or conductance) value. For example, the read circuit may measure a current C_{MS,+} capable of flowing through the cell 123_{MS,+}. The current C_{MS,+} therefore represents the actual programmed state of the cell 123_{MS,+}.

In the following description, for simplicity of exposure, the current values measured in the individual memory cells (both positive and negative) are considered as positive current values.

The programming error Err is therefore a function of the difference C_{T}−C_{MS,+}. In particular, the programming error may be calculated as the difference between the absolute value of the target value C_{T} and the measured current C_{MS,+}; e.g., Err=|C_{T}|−C_{MS,+}.

If the programming error Err is lower than zero (branch Y at the output of block 144), then (step 145) the read/write circuit 24 programs the most significant negative cell 123_{MS,-} as a function of the programming error Err; in particular, the cell 123_{MS,-} may be programmed so as to allow the flow of a current that is a function of (in particular is equal to) Err. The most significant negative cell 123_{MS,-} may then be programmed at a corrective state that depends on the programming error Err.

In detail, the read/write circuit 24 may perform an analog programming of the most significant negative cell 123_{MS,-}.

In response, at step 146, the read/write circuit 24 reads the value programmed in the most significant negative cell 123_{MS,-} In detail, the current C_{MS,-} capable of flowing in the most significant negative cell 123_{MS,-} is measured.

If, instead, at step 144 the programming error is not lower than zero, then (branch N), the read/write circuit 24 reads, at step 147, the value programmed in the most significant negative cell 123_{MS,-} at step 141.

In detail, the current C_{MS,-} capable of flowing in the most significant negative cell 123_{MS,-} is measured, in response to the reset performed at step 141.

In practice, at step 147, a parameter indicative of the programming error resulting from the reset of the most significant negative cell 123_{MS,-} is measured.

In response to steps 146 or 147, the read/write circuit 24 updates (step 148) the programming error Err, in such a way that the programming error Err is also a function of the current C_{MS,-}.

In detail, the programming error Err is also updated as a function of a significance parameter r. The significance parameter r is indicative of the lower significance associated with the cells 123_{LS,-} and 123_{LS,+} compared to the cells 123_{MS,-} and 123_{MS,+}.

In particular, in the embodiment shown, the updated programming error Err′ is calculated as: Err′=r. (|C_{T}|-(C_{MS,+}-C_{MS,-})).

In response to step 148, if the programming error Err′ is greater than zero (branch Y at the output of block 149), the read/write circuit 24 resets the least significant negative cell 123_{LS,-} Then, the read/write circuit 24 programs, at step 151, the least significant positive cell 123_{LS,+} at the programming error Err′, in particular through an analog programming; measures, at step 152, the current C_{LS,+} of the cell 123_{LS,+} resulting from the programming of the preceding step 151; and updates, at step 153, the programming error Err′ as a function of the current C_{LS,+}, that is Err”=Err′-C_{LS,+}.

In response, if the resulting error Err” is not lower than zero (branch N from block 154) then the programming of the computational weight Gᵢⱼ ends.

If, instead, at block 154 the error Err” is lower than zero (branch Y) then, the read/write circuit 24 proceeds, at step 155, with the programming (in particular, an analog programming) of the programming error Err” in the least significant negative cell 123_{LS,-}.

Following the writing of step 155, the programming of the computational weight Gᵢⱼ ends.

Returning again to block 148, wherein the calculated programming error Err′ is a function of the actual resistance values written in the most significant cells 123_{MS,+} and 123_{MS,-}, if the resulting error Err′ is not greater than zero (branch N from step 149), then it is verified whether the error Err is equal to zero (step 156).

If the error Err′ is equal to zero, branch Y at the output of step 156, then the read/write circuit 24 resets the cells 123_{LS,-} and 123_{LS,+}, that is it programs the cells 123_{LS,-} and 123_{LS,+} at the respective reset state R.

In response, the programming of the computational weight Gᵢⱼ ends.

If, instead, at step 156 it is verified that the programming error Err′ is different from zero (branch N), then (step 158) the read/write circuit 24 resets the cell 123_{LS,+}.

Then, the read/write circuit 24: programs, step 159, the cell 123_{LS,+} at the error Err′, in particular through an analog programming; measures, step 160, the current C_{LS,-} resulting from the writing of the cell 123_{LS,-}; and updates the programming error as a function of the current C_{LS,-}. In detail, Err′″=Err′−C_{LS,-}.

In response, if the resulting error Err′″ is not greater than zero (branch N from block 162) then the programming of the computational weight Gᵢⱼ ends.

If, instead, at block 162 the error Err′″ is greater than zero (branch Y), then the read/write circuit 24 proceeds, step 163, with the programming (in particular, an analog programming) of the programming error Err in the least significant positive cell 123_{LS,+}. Following the writing of step 155, the programming of the computational weight Gᵢⱼ ends.

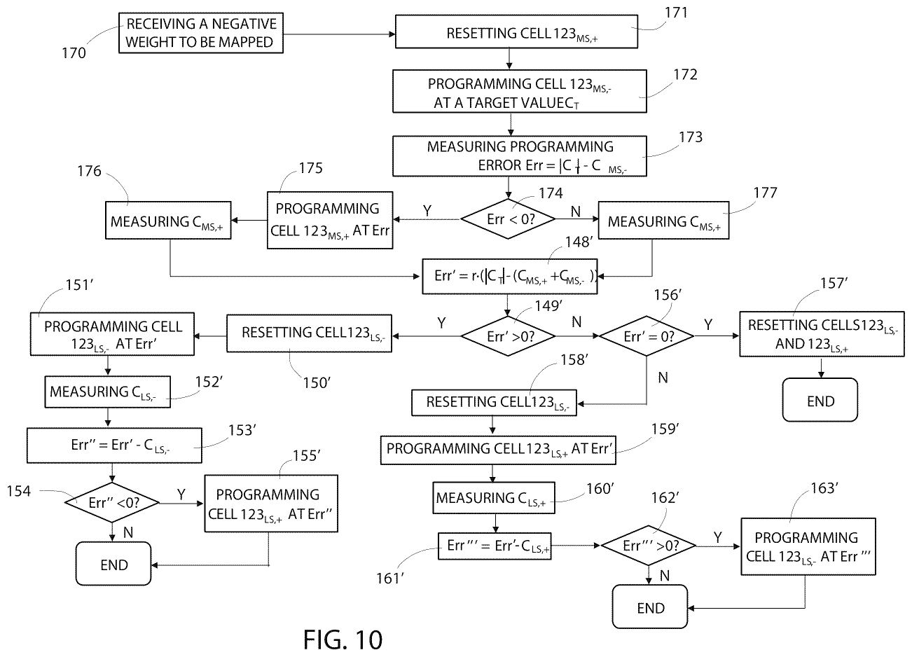

FIG. 10 shows a flow chart of a method for programming a weight Gᵢⱼ in the respective group of cells 122ᵢⱼ, in case the weight Gᵢⱼ is negative.

The read/write circuit 24 receives, step 170, the negative weight to be mapped Gᵢⱼ.

In particular, the weight Gᵢⱼ may be represented by a binary encoding of the weight to be mapped, or by a different encoding, depending on the specific implementation.

Also in this case, the target current value C_{T} corresponding to the current value that the group of cells 122ᵢⱼ is desired to provide during the execution of an in-memory computation operation is associated with the weight to be mapped Gᵢⱼ, similarly to what has been discussed above for FIG. 9.

Then, at step 171, the read/write circuit 24 resets the most significant positive cell 123_{MS,+}.

At step 172, the read/write circuit 24 programs the most significant negative cell 123_{MS,-} at the target current value C_{T}.

In detail, the read/write circuit 24 performs an analog programming of the cell 123_{MS,-}, similarly to what has been discussed for the method of FIG. 9.

According to one embodiment, the read/write circuit 24 may be configured to program the cell 123_{MS,-} at a current value lower than the target value C_{T}, for example at a value C_{T}−A, where the offset A may be defined as already discussed in reference to FIG. 6. For example, in the specific case considered where C_{T}<0, the cell 123_{MS,-} may be programmed at a current value that, in absolute value, is greater than the absolute value of C_{T}. This may allow to increase the programming precision of the weight Gᵢⱼ.

Then, step 173, the programming error Err resulting from step 172 is measured, similarly to what has been discussed for step 142 and therefore not repeated here in detail.

In detail, the read/write circuit 24 carries out a reading indicative of the resistance (or conductance) value written at step 172. For example, the read circuit may measure a current C_{MS,-} capable of flowing through the cell 123_{MS,-}.

The programming error Err is therefore a function of the difference C_{T}−C_{MS,-}, in particular |C_{T}|−C_{MS,-}.

If the programming error Err is lower than zero (branch Y at the output of block 174), then (step 175) the read/write circuit 24 programs the most significant positive cell 123_{MS,+} as a function of the programming error Err, in particular, the cell 123_{MS,+} may be programmed so as to allow the flow of a current that is a function of (in particular is equal to) Err.

In detail, the read/write circuit 24 may perform an analog programming of the most significant negative cell 123_{MS,-}.

In response, at step 176, the read/write circuit 24 reads the programmed value in the most significant positive cell 123_{MS,+}.

In detail, the current C_{MS,+} capable of flowing in the most significant positive cell 123_{MS,+} is measured.

If, instead, at step 174 the programming error is not lower than zero, then (branch N), the read/write circuit 24 reads, at step 177, the value programmed in the most significant positive cell 123_{MS,+} at step 171.

In detail, the current C_{MS,+} capable of flowing in the most significant positive cell 123_{MS,+} is measured, in response to the reset performed at step 171.

In practice, at step 177, a parameter indicative of the programming error resulting from the reset of the most significant positive cell 123_{MS,+} is measured.

In response to steps 176 or 177, the read/write circuit 24 updates the programming error Err, in such a way that the programming error Err′ is also a function of the current C_{MS,-}. The programming error Err may be updated similarly to what has been discussed for step 148 of FIG. 9, here indicated as step 148′; in particular, taking into account the mapping of a negative weight, the programming error may be updated as: Err′=r. (|C_{T}|-(C_{MS,-}+C_{MS,-})).

Subsequently, steps 149′ to 163′ are performed that are the same as, respectively, steps 149 to 163 described in reference to FIG. 9 except for the sign of the cells involved in the individual steps, as indicated in the diagram of FIG. 10. Therefore, steps 149′ to 163′ of FIG. 10 are indicated by adding a superscript to the corresponding reference numbers of FIG. 9. For example, if Err′>0 (branch Y from step 149′), at step 150′, the cell 123_{LS,+} is reset (instead of the cell 123_{LS,-} of step 150 of FIG. 9), at step 151′ the cell 123_{LS,-} is programmed (instead of the cell 123_{LS,+} of step 151 of FIG. 9), and so on.

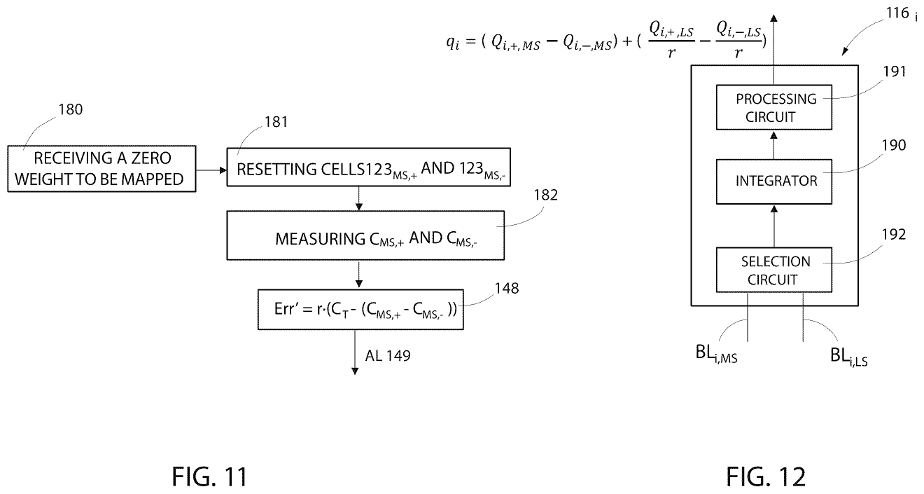

FIG. 11 shows a flowchart of a method for programming a weight Gᵢⱼ in the respective group of cells 122ᵢⱼ, in case the weight Gᵢⱼ is equal to zero.

The read/write circuit 24 receives, step 180, the weight to be mapped Gᵢⱼ=0.

In this case, the target current value C_{T} associated with the weight to be mapped Gᵢⱼ=0 may be a current value equal to zero or in any case lower than a threshold, depending on the specific current level associated with the reset state of the cells 120.

Therefore, in this case, step 181, the read/write circuit 24: resets both the most significant positive cell 123_{MS,+} and the most significant negative cell 123_{MS,-}; and, step 182, measures the current value C_{MS,+} actually written in the most significant positive cell 123_{MS,+} and the current value C_{MS,-} actually written in the most significant negative cell 123_{MS,-}.

In this case, the method then proceeds with step 148 of FIGS. 9 and 10; that is, the programming error Err′=r·(|C_{T}|−(C_{MS,+}−C_{MS,-})) is determined.

In response, the method proceeds with step 149 and following, already described in reference to FIGS. 9 and 10, therefore not further described here.

The methods of FIGS. 9-11 may therefore be used to program positive, negative and zero weights Gᵢⱼ in the groups of memory cells 122ᵢⱼ of the IMC device 100.

As emerges from the above, also in this embodiment, in case of a negative weight to be mapped, the programming of the positive cells depends on the programming error of the negative cells and, in case of a positive weight to be mapped, the programming of the negative cells depends on the programming error of the positive cells.

In particular, in this embodiment, if Gᵢⱼ<0, then the programming of the positive cell having greater significance (123_{MS,+}) may depend on the programming error of the negative cell having greater significance (123_{MS,-}); and if Gᵢⱼ>0, then the programming of the negative cell having greater significance (123_{MS,-}) may depend on the programming error of the positive cell having greater significance (123_{MS,+}).

Furthermore, in this embodiment, the negative cell and/or the positive cell having lower significance may be programmed as a function of the programming error Err′ that depends on the actual programmed state of both the positive cell having greater significance and the negative cell having greater significance.

Following the mapping of the computational weights into the memory array 12, the IMC device 100 may be used to perform an in-memory computation operation such as, for example, a MAC operation.

Also in this embodiment, the row activation unit 14 is configured to receive an input signal X indicative of the input data x₁, . . . , x_{N} of the MAC operation to be performed. The row activation unit 14 is configured to provide, for each input datum xⱼ, a positive activation signal S_{j,+} and a negative activation signal S_{j,-} as a function of the respective input datum xⱼ.

In particular, the activation signals S_{j,+}, S_{j,-} are configured to activate the memory cells 120 coupled to the word lines WL_{j,+}, WL_{j,-} for an activation duration that depends on the input datum xⱼ, in particular it depends on the absolute value and/or sign of the input datum xⱼ.

The IMC device 100 comprises a plurality of digital detectors 116₁, . . . , 116L, each coupled to a respective most significant bit line BL_{i,MS} and to a respective least significant bit line BLᵢ,LS.

Purely by way of example, the digital detector 116₁ is coupled to the bit line BL₁ (corresponding to the most significant bit line BL_{1,MS} of the groups of cells 122_{i,1}, . . . , 122_{i,N} in the arrangement of FIG. 7) and to the bit line BL2 (corresponding to the least significant bit line BL_{1,LS} of the groups of cells 122_{i,1}, . . . , 122_{i,N} in the arrangement of FIG. 7).

Each digital detector 116; is configured, during respective computational windows, to detect: an amount of most significant positive charge Q_{i,+,MS} that flows in the bit line BL_{i,MS} in response to the activation of the most significant positive cells 123_{MS,+} that are coupled to the bit line BLᵢ,MS; an amount of most significant negative charge Q_{i,-,MS} that flows in the bit line BL_{i,MS} in response to the activation of the most significant negative cells 123_{MS,-} that are coupled to the bit line BLᵢ,MS; an amount of least significant positive charge Q_{i,+,LS} that flows in the bit line BLᵢ,LS in response to the activation of the least significant positive cells 123_{LS,+} that are coupled to the bit line BL_{i,LS}; and an amount of least significant negative charge Q_{i,-,LS} that flows in the bit line BLᵢ,LS in response to the activation of the least significant negative cells 123_{LS,-} that are coupled to the bit line BLᵢ,LS.

Furthermore, each digital detector 116; is configured to provide a digital signal qᵢ that is indicative of:

$$( {Q}_{i , + , MS} - {Q}_{i , - , MS} ) + ( \frac{{Q}_{i , + , LS}}{r} - \frac{{Q}_{i , - , LS}}{r} ) ,$$

that is, the digital detector 116; is configured to divide the least significant charge contributions by the factor r used during the programming of the respective least significant cells.

For the purposes of the present description, the charge contributions Q_{i,+},MS, Q_{i,-},MS, Q_{i,+,LS} and Q_{i,-,LS} are to be understood in absolute value, that is as values of a charge having a positive sign.

In detail, according to one embodiment, as shown in FIG. 12, each digital detector 116; may comprise an integrator 190 configured to integrate the current that flows in the respective bit line; and a processing circuit 191 configured to perform one or more operations on the measured charge contributions, in such a way as to provide the signal qᵢ.

Each digital detector 116; may further comprise a selection circuit 192 configured to couple the integrator 190 to the most significant bit line BL_{i,MS} or to the least significant bit line BLᵢ,LS.

FIG. 13 shows a schematic representation of the execution of a MAC operation by the IMC device 100, according to one embodiment, wherein the execution of the MAC operation comprises four computation windows CW_{MS,+}, CW_{MS,-}, CW_{LS,+}, CW_{LS,-}, distinct from each other.

In the embodiment shown in FIG. 13, the computation windows CW_{MS,+}, CW_{MS,-} associated with the most significant cells are executed temporally before the computation windows CW_{LS,+}, CW_{LS,-} associated with the least significant cells.

In the computation window CW_{LS,+}, the row activation unit 14 provides the positive activation signals S_{1,+}, . . . , S_{N,+} and the digital detectors 116₁, . . . , 116_{L} each measure the least significant positive charge Q_{i,+,LS} that flows in the respective least significant bit lines BLᵢ,LS.

In the computation window CW_{LS,-}, the row activation unit 14 provides the negative activation signals S_{1,-}, . . . , S_{N,-} and the digital detectors 116_{L} . . . , 116_{L} each measure the least significant negative charge Q_{i,-,LS} that flows in the respective least significant bit lines BLᵢ,LS.

In the computation window CW_{MS,+}, the row activation unit 14 provides the positive activation signals S_{1,+}, . . . , S_{N,+} and the digital detectors 116₁, . . . , 116_{L} each measure the most significant positive charge Q_{i,+,MS} that flows in the respective most significant bit lines BLᵢ,MS.

In the computation window CW_{MS,-}, the row activation unit 14 provides the negative activation signals S_{1,-}, . . . , S_{N,-} and the digital detectors 116₁, . . . , 116_{L} each measure the most significant negative charge Q_{i,-,MS} that flows in the respective most significant bit lines BLᵢ,MS. In the embodiment of FIG. 13, the digital detectors 116₁, . . . , 116_{L} are each configured to detect the charge contributions Q_{i,+},MS, Q_{i,+,LS}, Q_{i,-,MS} and Q_{i,-,LS} during the respective computational windows CW_{MS,+}, CW_{LS,+}, CW_{MS,-} and CW_{LS,-}. This allows the execution of the in-memory computation operation to be sped up by the IMC device 100.

Furthermore, in the embodiment of FIG. 13, the digital detectors 116₁, . . . , 116_{L} are also each configured to process the charge contributions Q_{i,+},MS, Q_{i,+,LS}, Q_{i,-,MS} and Q_{i,-,LS} measured during the respective computational windows CW_{MS,+}, CW_{LS,+}, CW_{MS,-} and CW_{LS,-}. This allows the execution of the in-memory computation operation to be further sped up by the IMC device 100.

In the example shown in FIG. 13, the computation windows CW_{LS,+}, CW_{LS,+}, CW_{LS,+}, CW_{LS,+} all have the same duration TC; however, the computation windows CW_{LS,+}, CW_{LS,+}, CW_{LS,+}, CW_{LS,+} may have different durations from each other, depending on the specific application and implementation.

Furthermore, in the example shown in FIG. 13, for each input datum xⱼ, the positive activation signal S_{j,+} has the same activation duration T(xⱼ) as the respective negative activation signal S_{j,-}; however, the activation signals S_{j,+}, S_{j,-} may have different durations from each other, depending on the specific application and implementation.

Furthermore, in the example shown in FIG. 13, for each input datum xⱼ, the positive activation signal S_{j,+} provided during the computation window CW_{LS,+} has the same activation duration T(xⱼ) as the positive activation signal S_{j,+} provided during the computation window CW_{MS,+}, and the negative activation signal S_{j,-} provided during the computation window CW_{LS,-} has the same activation duration T(xⱼ) as the negative activation signal S_{j,-} provided during the computation window CW_{MS,-}. However, the activation signal S_{j,+} and/or the activation signal S_{j,-} may have different durations from each other between the most significant window (e.g., CW_{MS,+}) and the least significant window (e.g., CW_{LS,+}), depending on the specific application and implementation.

In practice, it will be clear to the person skilled in the art that the programming of the computational weights described with reference to the IMC device 100, allows to obtain a computation error ε_{w}, during the execution of an in-memory computation operation, equal to:

$${ε}_{w} = 2 \cdot {ε}_{r} + 2 \cdot {ε}_{r} / r + {ε}_{max} / r ,$$

where r is the significance parameter used during the mapping of the computational weights into the memory array 12 and for the processing of the least significant charge contributions Q_{i,+,LS}, Q_{i,-,LS}; the term 2·εᵣ is indicative of the maximum reading error that is obtained from the measurement of the most significant charge contributions Q_{i,+},MS, Q_{i,-},MS; the term 2·εᵣ/r is indicative of the reading error that is obtained from the measurement of the least significant charge contributions Q_{i,+,LS}, Q_{i,-,LS}; and the term Emax/r is indicative of the maximum programming error of one or more of the levels or states at which the memory cells 120 may be programmed.

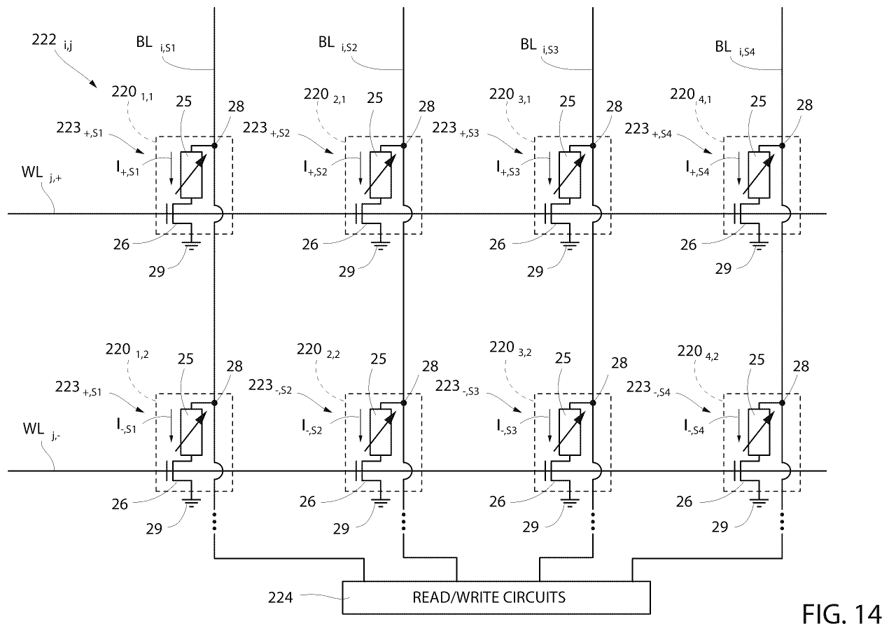

With reference to FIGS. 14-16, a further embodiment of a method for mapping the computational weights into the memory cells of the present IMC device is described.

In detail, FIG. 14 shows a portion of a memory array, whose general structure may be similar to the array 12 of FIGS. 1 and 7, comprising a plurality of memory cells organized according to a matrix structure similarly to what has been discussed for FIGS. 1 and 7, and therefore not further discussed herein.

Furthermore, with reference to the embodiment of FIG. 14, the memory cells are organized so as to form a plurality of groups of memory cells, each indicated by 222_{i,j} and each configured to map a respective computational weight Gᵢⱼ.

Each group of memory cells 222_{i,j} comprises a number T≥2 of positive cells and a number T≥2 of negative cells.

In particular, in the embodiment of FIG. 14, each group of memory cells 222_{i,j}, comprises eight memory cells, of which four positive cells exemplarily indicated by 220_{1,1}, . . . , 220_{4,1} and four negative cells exemplarily indicated by 220_{1,2}, . . . , 220_{4,2}. In practice, the number of positive cells and negative cells T is equal to four in the example considered.

Each cell of the group of cells 222_{i,j}, when programmed, is configured to provide a respective current. In the following, the current of a generic positive cell 223_{+,Sn} is indicated by I_{+,Sn} and the current of a generic negative cell 223_{-,Sn} is indicated by I_{+,Sn}. For example, for n=1, the current of the positive cell 223_{+,S1} is indicated by I_{+,S1} and the current of the negative cell 223_{-,S1} is indicated by I_{-,S1}.

In particular, the currents I_{+,Sn}, I_{-,Sn} indicate the currents that the respective cells would be capable of providing during the execution of an in-memory computation operation, for example in response to the activation by the respective activation signals S_{j,+}, S_{j,-} discussed above and in response to the reception of the bias signal (for example a bias voltage) used to bias the memory cells.

For the purposes of the present description, by way of example, the currents I_{+,Sn}, I_{-,Sn} are understood in absolute value, that is as positive current values.

The IMC device is configured, during the execution of an in-memory computation operation, to assign to the positive cells 220_{1,1}, 220_{2,1}, 220_{3,1}, 220_{4,1} different significance from each other, in particular they have decreasing significance with respect to each other, and in the following they are also indicated respectively by 223_{+,S1}, 223_{+,S2}, 223_{+,S3}, 223_{+,S4}; and to assign to the negative cells 220_{1,2}, 220_{2,2}, 220_{3,2}, 220_{4,2} different significance from each other, in particular decreasing significance and in the following they are also indicated respectively by 223_{-,S1}, 223_{-,S2}, 223_{-,S3}, 223_{-,S4}.

For example, similarly to what has already been described in reference to FIGS. 12 and 13, the different significance may be assigned during the detection, by the digital detector, of the charge flowed in the bit lines during the respective computational windows.

In other words, each cell of the group of cells 222_{i,j} is configured to provide, during the execution of an in-memory computation operation, an actual current contribution that depends on the respective programmed current and on the respective significance.

For example, the weighted current contribution of a generic positive cell 223_{+,Sn} may be I_{+,Sn}/2ⁿ⁻¹ and the weighted current contribution of a generic negative cell 223_{-,Sn} may be I_{-,Sn}/2ⁿ⁻¹. Therefore, the weighted current contribution of the positive cell 223_{+,S1} may be I_{+,S1} and the weighted current contribution of the positive cell 223_{+,S2} may be I_{+,S2}/2.

Therefore, during the execution of an in-memory computation operation, the IMC device is configured to assign to each group of cells 222_{i,j}, an actual overall current contribution Rₑ equal to

$${\sum }_{n = 1}^{T} ( {I}_{+ , Sn} - {I}_{- , Sn} ) / {2}^{n - 1} .$$

In the exemplary configuration of FIG. 14, the positive cells 223_{+,S1}, 223_{+,S2}, 223_{+,S3}, 223_{+,S4} are coupled to a same word line WL_{j,+}, and the negative cells 223_{-,S1}, 223_{-,S2}, 223_{-,S3}, 223_{-,S4} are coupled to a same word line WL_{j,-}.

Furthermore, in the exemplary configuration of FIG. 14, cells having equal significance are coupled to the same bit line. In detail, the cells 223_{+,S1} and 223_{-,S1} are coupled to a bit line BL_{i,S1}; the cells 223_{+,S2} and 223_{-,S2} are coupled to a bit line BL_{i,S2}; the cells 223_{+,S3} and 223_{-,S3} are coupled to a bit line BL_{i,S3}; the cells 223_{+,S4} and 223_{-,S4} are coupled to a bit line BL_{i,S4}.

The memory cells of each group 222_{i,j} each comprise also here a storage element 25 programmable in such a way as to have a specific resistance level, and a selection element 26, arranged between node 28 and reference node 29.

In detail, in this embodiment, it is considered that each storage element 25 may be digitally programmed at two levels or states, including a high-resistance reset state R and a low-resistance set state S.

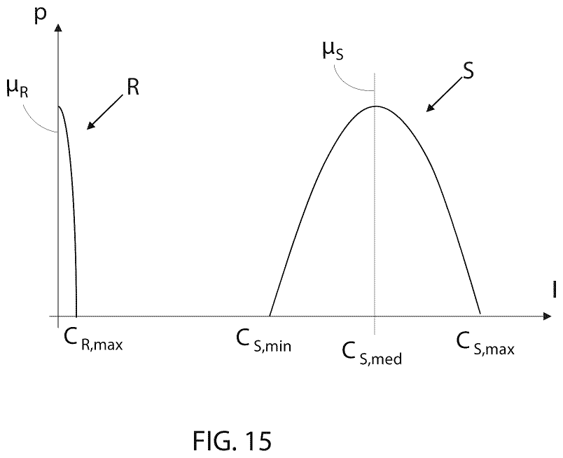

Purely by way of example, FIG. 15 shows an example of the probability distributions of the states R, S, wherein the probability distribution of the reset state R has a mean value UR equal to zero and a maximum current value equal to C_{R,max} (for example of the order of a few microamps), and wherein the probability distribution of the set state S extends between a minimum value C_{S,min} (greater than CR,max) and a maximum value C_{S,max} and has a mean value us equal to C_{S,med} (for example, the maximum programming error of the set state equal to (C_{S,max}−C_{S,min})/2 may be of the order of a few tens of microamps).

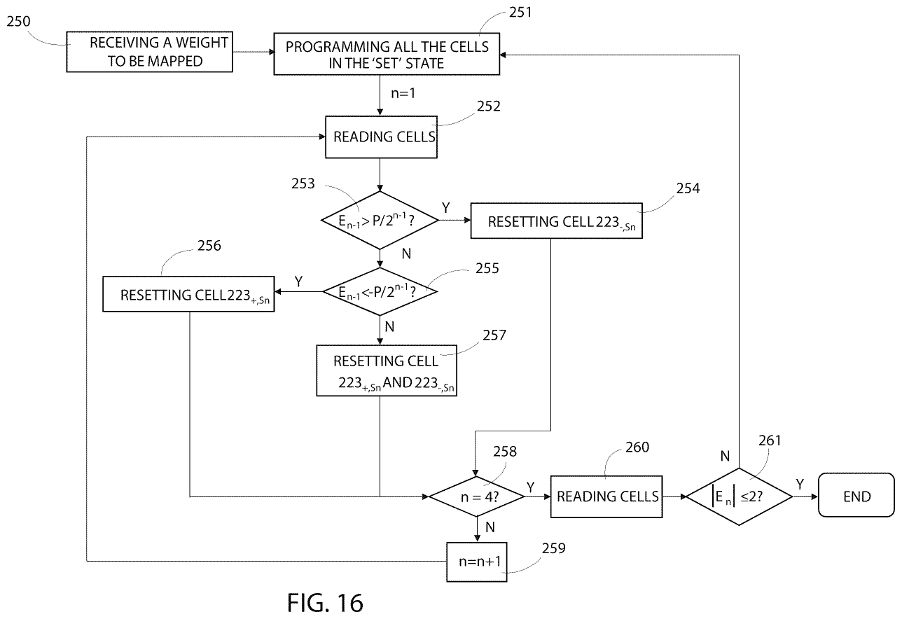

FIG. 16 shows a flowchart of a method for mapping a computational weight Gᵢⱼ into the group of cells 222_{i,j}.

The programming of the group of cells 222_{i,j} may be performed by a read/write circuit 224.

At a step 250, a weight Gᵢⱼ is received to be mapped into the group of cells 222_{i,j.}

Similarly to what has been previously discussed, an encoding, for example a binary encoding, and a target current level C_{T} that is desired to be programmed in the group of cells 222_{i,j}, may correspond to the weight Gᵢⱼ.

The target current level C_{T} is the theoretical overall current contribution Rt that the group of cells 222_{i,j} is desired to provide during the execution of an in-memory computation operation. In other words, theoretically, following the programming of the cells of the group of cells 222_{i,j}, the actual overall current contribution Re that the group of cells 222_{i,j} will be capable of providing during the execution of an in-memory computation operation should be equal to the target current level C_{T}.

In particular, the overall current contribution of the group 222_{i,j} during the execution of the in-memory computation operation, depends on the difference between the sum of the positive weighted current contributions (i.e. provided by the set of positive cells 223_{+,Sn}) and the sum of the negative weighted current contributions (i.e. provided by the set of negative cells 223_{-,Sn}).

Initially, step 251, all memory cells 223_{+,S1}, 223_{+,S2}, 223_{+,S3}, 223_{+,S4} and 223_{-,S1}, 223_{-,S2}, 223_{-,S3}, 223_{-,S4} of the group of cells 222_{i,j} may each be programmed at the set state S.

The programming of the cells may, in this embodiment, be a digital programming, that is a programming configured to program each memory cell 220 at one of two states (reset or set state). In other words, the digital programming may be defined as a non-multilevel programming, that is with the number of levels equal to two.

Furthermore, an iteration index n is set to an initial value, e.g. n=1.

Then, step 252, the read/write circuit 224 reads the memory cells of the group of cells 222_{i,j}.

For each cell of the group of cells 222_{i,j} a parameter indicative of the resistance value actually programmed in the cell is measured.

In detail, the read/write circuit 224 may measure, for each positive cell 223_{+,Sn} and each negative cell 223_{-,Sn} of the group of cells 222_{i,j}, the respective current values I_{+,Sn} and I_{+,Sn}.

In practice, with reference to the example of FIG. 15, reading the memory cells of the group 222_{i,j} allows to measure, among the current values of the distribution associated with the set state S, at which current value the cells have actually been programmed.

At the first iteration, for n=1, step 252 may be omitted.

Furthermore, a parameter En is determined indicative of the programming error of the memory cells of the group of cells 222_{i,j.}

In detail, the parameter En may be defined by:

$${E}_{n} = {C}_{T} - {\sum }_{k = 1}^{n} \frac{( {I}_{+ , Sk} - {I}_{- , Sk} )}{{2}^{k - 1}} .$$

Furthermore, an initial value of the parameter E may be defined: E₀=C_{T}, that is the initial value is equal to the target current value C_{T}.

Successively, step 253, the read/write circuit 224 compares the parameter En-1 with a threshold P/2ⁿ⁻¹, where P may indicate the programmable range of the memory cells of the group 222_{i,j}. The parameter P is a function of the width of the probability distribution of the set state and of the respective number of positive (or negative) memory cells, that is equal to four in the example considered.

In particular, the parameter P may be defined as

$$P = ( {C}_{S , min} - {C}_{R , max} ) .$$

For example, the parameter P may be chosen during a calibration or initialization of the IMC device.

At the first iteration, for n=1, the read/write circuit 224 may thus compare the parameter E₀=C_{T} with the threshold P/2n-1=P.

If E₀>P, branch Y from block 253, then the read/write circuit 224 resets the negative cell 223_{-,Sn} that is, at the first iteration, the negative cell 223_{-,S1}, which is the most significant among the negative cells of the group of cells 222_{i,j.}

Conversely, if E₀ is not greater than P, branch N from block 253, and is lower than −P, branch Y from block 255, then the read/write circuit 224 resets (step 256) the positive cell 223_{+,Sn} that is, at the first iteration, the positive cell 223_{+,S1}, which is the most significant among the positive cells of the group of cells 222_{i,j.}

If instead, at block 255, E₀ is not greater than P, branch N from block 253, and is not lower than −P, branch N from block 255, then the read/write circuit 224 resets (step 257) both the positive cell 223_{+,Sn} and the negative cell 223_{-,Sn} that is, at the first iteration, both the most significant cells 223_{+,S1} and 223_{-,S1} of the group of cells 222_{i,j.}

In response to one of the steps 254, 256 or 257, the method proceeds to verify, step 258, whether n=4, that is whether all the B=4 positive cells and the B=4 negative cells have been programmed.

In the negative case, branch N, the iteration index n is updated: n=n+1 (step 259).

The method then returns to step 252 and a second iteration (n=2) begins, wherein the read/write circuit 224 reads all the positive cells and all the negative cells of the group 222_{i,j.}

In detail, the read/write circuit 224 measures, for each positive cell 223_{+,Sn} and each negative cell 223_{-,Sn}, the respective current I_{+,Sn} and I_{+,Sn}.

The read/write circuit 224 then determines an updated value of the programming error Eₙ₋₁=E₁ indicative of the programming error occurred during the preceding iteration n=1, in particular:

$${E}_{1} = {C}_{T} - {\sum }_{k = 1}^{1} \frac{( {I}_{+ , Sk} - {I}_{- , Sk} )}{{2}^{k - 1}} = {C}_{T} - \frac{( {I}_{+ , S 1} - {I}_{- , S 1} )}{1} .$$

Similarly to what has been discussed for the preceding iteration, the programming error E₁ is compared with P/2ⁿ⁻¹, that is now P/2.

If the programming error E₁ is greater than P/2, then the read/write circuit 224 resets (step 254) the negative cell 223−,S2; if the programming error E₂ is lower than −P/2, then the read/write circuit 224 resets (step 256) the positive cell 223_{+,S2}; if instead-P/2<E₂<P/2, then the read/write circuit 224 resets (step 257) both the negative cell 223_{-,S2} and the positive cell 223_{+,S2}.

The iteration index is updated again, n=n+1=3 (step 259) and the method returns to step 252.

During the third iteration with n=3, the programming error E₂ related to the preceding iteration n=2 is determined:

$${E}_{2} = {C}_{T} - {\sum }_{k = 1}^{2} \frac{( {I}_{+ , Sk} - {I}_{- , Sk} )}{{2}^{k - 1}} = {C}_{T} - \frac{( {I}_{+ , S 1} - {I}_{- , S 1} )}{1} - \frac{( {I}_{+ , S 2} - {I}_{- , S 2} )}{2} ,$$

that depends on the actual current value at which one or both of the positive cell 223_{+,S2} and the negative cell 223_{+,S2} have been programmed.

As a function of the comparison of the programming error with P/22=P/4, the read/write circuit 224 resets one or both of the positive cell 223_{+,S3} and the negative cell 223_{-,S3}, similarly to what has been discussed in reference to the preceding iteration (for n=2).

A last iteration (n=4) is then executed, in a manner similar to what has been described above for the preceding iterations and therefore not further described in detail.

At the end of the iteration for n=4, the method exits the loop, branch Y from block 258, and the read/write circuit 224 reads (step 260) all the cells of the group of cells 222_{i,j}; and determines a final value of the programming error Eₙ=E₄.

The final value of the programming error E₄ is compared with a threshold, equal to 1 in the example shown and, in particular, verifies that |E₄|≤2.

In the affirmative case, the programming of the computational weight Gᵢⱼ in the group of cells 222_{i,j} ends, since the overall final programming error of the respective eight cells is lower than the desired value.

If, conversely, the absolute value of the final programming error E₄ is not lower than or equal to the threshold value, branch N from block 261, then the method can return to step 251, wherein all the memory cells of the group of cells 222_{i,j} are again programmed at the respective set state S. In practice, the programming of the weight Gᵢⱼ starts again from the beginning, since the final error obtained was not sufficiently low.

The entire programming method (i.e., branch N from step 261) may be repeated for a number of times that may be chosen by the user during the calibration, initialization or programming step of the memory array, depending on the specific application; for example, up to a maximum of 10 times or less, in particular 4 times. This allows to obtain a high programming precision and at the same time keep the programming times low.

The described method may be repeated to program an entire memory array, in such a way that each group of cells 222_{i,j} maps a respective computational weight Gᵢⱼ.

In practice, according to the method described in reference to FIG. 16, the memory cell having greater significance is first programmed at its respective set state, that is the one configured to map the most significant bit of the weight Gᵢⱼ, that corresponds to the sign of the weight Gᵢⱼ while the opposite cell having greater significance is programmed at its respective reset state R (for example, in case of positive weight, the cell 223_{+,S1} is programmed at its respective set state and the cell 223_{-,S1} is programmed at its respective reset state).

Successively, the second cells 223_{+,S2}, 223_{-,S2} are programmed as a function of the residual programming error indicative of the difference between the overall target current value C_{T} and the current contribution (I_{+,S1}-I_{-,S1}) provided by the most significant cells.

Subsequently, the third cells 223_{+,S3}, 223_{-,S3} are programmed as a function of the residual programming error indicative of the difference between the overall target current value C_{T}, the current contribution (I_{+,S1}-I_{-,S1}) provided by the cells 223_{+,S1}, 223_{-,S1} and the weighted current contribution ((I_{+,S2}-I_{-,S2})/2) provided by the cells 223_{+,S2}, 223_{-,S2}.

Subsequently, the fourth cells 223_{+,S4}, 223_{-,S4} are programmed as a function of the residual programming error indicative of the difference between the overall target current value C_{T}, the current contribution (I+,S1-I−,S1) provided by the cells 223_{+,S1}, 223_{-,S1}, the weighted current contribution ((I_{+,S2}-I_{-,S2})/2) provided by the cells 223_{+,S2}, 223_{-,S2}, and the weighted current contribution ((I_{+,S3}-I_{-,S3})/4) provided by the cells 223_{+,S3}, 223−,S3.

It emerges from the above that the programming method described in reference to FIG. 16 allows to correct, during the mapping of each computational weight, deviations in the programming of the cells with respect to the desired value.

The method may therefore have a high programming precision.

Consequently, the method also allows to obtain a high precision in the execution of in-memory computation operations.

Finally, it is clear that modifications and variations may be made to what has been described and illustrated above without thereby departing from the scope of the present invention, as defined in the attached claims.

For example, the programming methods described and illustrated above may be applied to groups of memory cells comprising a different number of memory cells with respect to what considered above, depending on the specific application.

With reference to any of the arrangements of FIGS. 1, 7 and 14, the memory cells may be arranged in a different manner, for example in such a way that the memory cells of a same group of cells are not coupled to adjacent bit lines and/or word lines. In addition or alternatively, the positive cells and the negative cells of a same group of cells may each be coupled to a respective bit line (i.e., to bit lines different from each other).

For example, with reference to what has been discussed in relation to FIG. 13, the order in which the computation windows are executed may be different from what has been shown.

For example, with reference by way of example to the embodiment of FIG. 7, each bit line may be coupled to a respective digital detector, in such a way that all the computation windows relating to cells of a same polarity (for example the windows CW_{LS,+} and CW_{MS,+}) are executed simultaneously with each other.

The IMC device may also comprise further circuits, units, blocks and the like, not shown here, that may be useful for the operation of the IMC device during the programming of the respective memory array and/or during the execution of an in-memory computation operation, such as for example known interface circuits.

For example, the memory cells may be resistive memory cells not based on PCM materials, but on different technologies; for example, they may be magnetoresistive (MRAM), resistive (RRAM) or static (SRAM) memory cells.

For example, the IMC device may comprise an output processing circuit having a number of digital detectors and/or DSPs different from what has been shown.

Finally, the embodiments described above may be combined to provide further solutions.

1. An in-memory computation (IMC) device configured to perform an in-memory computation operation, wherein the IMC device comprises:
a memory array including a group of memory cells configured to provide an overall current contribution during an execution of the in-memory computation operation;
the group of memory cells comprising a first set of memory cells configured to provide, during the execution of the in-memory computation operation, a first current contribution that is a function of a programming of the first set of memory cells, and a second set of memory cells configured to provide, during the execution of the in-memory computation operation, a second current contribution that is a function of a programming of the second set of memory cells, wherein the overall current contribution is a function of a difference between the first current contribution and the second current contribution; and
a programming circuit configured to map a signed computational weight into the group of memory cells by operating to:
program at least one memory cell of the first set of memory cells at a first programming state based on the computational weight;
detect a programming error of the at least one memory cell of the first set of memory cells, wherein the programming error is indicative of an error between a target programming state of the at least one memory cell of the first set of memory cells and an actual programmed state of the at least one memory cell of the first set of memory cells; and
program at least one memory cell of the second set of memory cells at a second programming state which includes a corrective value based on the programming error.

2. The IMC device according to claim 1, wherein the first programming state corresponds to a target value of an electrical quantity of the at least one memory cell of the first set of memory cells and the corrective value corresponds to a corrective value of said electrical quantity of the at least one memory cell of the second set of memory cells, the programming error being indicative of a difference between the target value of the electrical quantity and an actual value of the electrical quantity that has been programmed in the at least one memory cell of the first set of memory cells.

3. The IMC device according to claim 2, wherein the computational weight to be mapped is associated with a first theoretical value of the electrical quantity of the at least one memory cell of the first set of memory cells, and the target value of the electrical quantity of the at least one memory cell of the first set of memory cells is one of greater or lower than the first theoretical value.

4. The IMC device according to claim 2, wherein the electrical quantity of the memory cell is indicative of an amount of current provided by the memory cell, for example one of: resistance, conductance, current.

5. The IMC device according to claim 1:
wherein the first set of memory cells comprises a first memory cell configured to provide a current contribution having a first significance during the execution of the in-memory computation operation, and a second memory cell configured to provide a current contribution having a second significance during the execution of the in-memory computation operation, wherein the second significance is lower than the first significance, and wherein the first current contribution is a function of a sum of the current contributions of the first and second memory cells of the first set of memory cells weighted as a function of the first and second significances;
wherein the second set of memory cells comprises a third memory cell configured to provide a current contribution having a third significance during the execution of the in-memory computation operation, and a fourth memory cell configured to provide a current contribution having a fourth significance during the execution of the in-memory computation operation, wherein the fourth significance is lower than the third significance, and wherein the second current contribution is a function of a sum of the current contributions of the third and fourth memory cells of the second set of memory cells weighted as a function of the third and fourth significances;
wherein the programming error is a first programming error; and
wherein the programming circuit is configured to:
program the first memory cell of the first set of memory cells at the first programming state; and
program at least one of the third memory cell and the fourth memory cell of the second set of memory cells as a function of the first programming error of the first memory cell of the first set of memory cells.

6. The IMC device according to claim 5, further configured, in response to programming the third memory cell of the second set of memory cells, to:
detect a second programming error indicative of a difference between the first programming state, the actual programmed state of the first memory cell of the first set of memory cells, and an actual programmed state of the third memory cell of the second set of memory cells; and
program at least one of the second memory cell of the first set of memory cells and the fourth memory cell of the second set of memory cells, based on the second programming error.

7. The IMC device according to claim 6, wherein the second programming error is also a function of a significance parameter indicative of at least one of: a ratio between the first significance and the second significance and a ratio between the third significance and the fourth significance.

8. The IMC device according to claim 5, wherein one of the first memory cells of the first set of memory cells and the third memory cell of the second set of memory cells is configured to map the most significant bit of the computational weight, the programming circuit being configured to:
program at a set state one of the first memory cell of the first set of memory cells and the third memory cell of the second set of memory cells, based on the sign of the computational weight to be mapped, and program at a reset state the other of the first memory cell of the first set of memory cells and the third memory cell of the second set of memory cells;
detect the actual programmed state of the first memory cell of the first set of memory cells and the actual programmed state of the third memory cell of the second set of memory cells;
determine a first actual current contribution of the first memory cell of the first set of memory cells and the third memory cell of the second set of memory cells as a function of a difference between the actual programmed state of the first memory cell of the first set of memory cells and the actual programmed state of the third memory cell of the second set of memory cells;
determine the first programming error as a function of the difference between the overall current contribution associated with the computational weight to be mapped and the first actual current contribution of the first memory cell of the first set of memory cells and the third memory cell of the second set of memory cells; and
program the second memory cell of the first set of memory cells and the fourth memory cell of the second set of memory cells based on the first programming error.

9. The IMC device according to claim 8:
wherein the first set of memory cells further comprises at least one fifth memory cell configured to provide a current contribution having a fifth significance during the execution of the in-memory computation operation, wherein the fifth significance is lower than the second significance, and wherein the first current contribution is a function of a sum of the current contributions of the first, second and at least one fifth memory cell of the first set of memory cells weighted as a function of their respective significances;
wherein the second set of memory cells further comprises at least one sixth memory cell configured to provide a current contribution having a sixth significance during the execution of the in-memory computation operation, wherein the sixth significance is lower than the fourth significance, and wherein the second current contribution is a function of a sum of the current contributions of the first, second and at least one sixth memory cell of the second set of memory cells weighted as a function of their respective significances;
wherein the programming circuit is further configured to:
detect an actual programmed state of the second memory cell of the first set of memory cells and an actual programmed state of the fourth memory cell of the second set of memory cells;
determine a second actual current contribution of the second memory cell of the first set of memory cells and the fourth memory cell of the second set of memory cells as a function of a difference between the actual programmed state of the second memory cell of the first set of memory cells and the fourth memory cell of the second set of memory cells;
determine the second programming error as a function of the difference between the overall current contribution associated with the computational weight to be mapped, the first actual current contribution of the first memory cell of the first set of memory cells and the third memory cell of the second set of memory cells, and the second actual current contribution of the second memory cell of the first set of memory cells and the fourth memory cell of the second set of memory cells; and
program the at least one fifth memory cell of the first set of memory cells and the at least one sixth memory cell of the second set of memory cells based on the second programming error.

10. The IMC device according to claim 1, wherein the programming circuit is configured to perform one of digital or analog programming of the memory cells of the first set of memory cells and the second set of memory cells.

11. The IMC device according to claim 1, wherein the programming circuit is configured to:
read the actual programmed state of at least one memory cell of the first set of memory cells that has been obtained in response to programming the at least one memory cell of the first set of memory cells at the first programming state; and
determine an error between the target programming state and the actual programmed state, the programming error being a function of the error between the target programming state and the actual programmed state.

12. The IMC device according to claim 1, further comprising:
an activation circuit configured to activate the memory cells of the group of memory cells during the execution of the in-memory computation operation, wherein each memory cell is activated for an activation duration that is a function of a respective input datum of the in-memory computation operation; and
an output detection circuit configured to detect an overall electrical charge as a function of the overall current contribution of the group of memory cells and the activation duration of the memory cells of the group of memory cells.

13. The IMC device according to claim 1, wherein the memory cells are variable-resistance non-volatile memory cells.

14. The IMC device according to claim 13, wherein the variable-resistance non-volatile memory cells are phase change memory cells.

15. The IMC device according to claim 1, wherein the corrective value comprises an offset, dependent on the programming error, from a theoretical value for the second programming state.

16. A method for mapping a signed computational weight into a group of memory cells of a memory array of an in-memory computation (IMC) device configured to perform an in-memory computation operation, wherein the group of memory cells is configured to provide an overall current contribution during the execution of the in-memory computation operation which is a function of the signed computational weight, and wherein the group of memory cells comprises a first set of memory cells configured to provide a first current contribution during the execution of the in-memory computation operation that is a function of the programming of the first set of memory cells, and a second set of memory cells configured to provide a second current contribution during the execution of the in-memory computation operation that is a function of the programming of the second set of memory cells, the overall current contribution being a function of a difference between the first current contribution and the second current contribution, the method comprising:
programming at least one memory cell of the first set of memory cells at a first programming state based on the computational weight;
detecting a programming error of the at least one memory cell of the first set of memory cells, the programming error being indicative of an error between a target programming state of the at least one memory cell of the first set of memory cells and an actual programmed state of the at least one memory cell of the first set of memory cells; and
programming at least one memory cell of the second set of memory cells at a second programming state including a corrective value based on the programming error.

17. The method according to claim 16, wherein the first programming state corresponds to a target value of an electrical quantity of the at least one memory cell of the first set of memory cells and the corrective value corresponds to a corrective value of said electrical quantity of the at least one memory cell of the second set of memory cells, the programming error being indicative of a difference between the target value of the electrical quantity and an actual value of the electrical quantity that has been programmed in the at least one memory cell of the first set of memory cells.

18. The method according to claim 16, further comprising:
reading the actual programmed state of at least one memory cell of the first set of memory cells that has been obtained in response to programming the at least one memory cell of the first set of memory cells at the first programming state; and
determining an error between the target programming state and the actual programmed state, the programming error being a function of the error between the target programming state and the actual programmed state.
